(19) United States
(12) Patent Application Publication
(10) Pub. No.: US 2009/0059501 A1
(43) Pub. Date: Mar. 5, 2009

(54) IMAGE DISPLAY UNIT AND FACE PIECE UNIT

(75) Inventor: Hiroshi YAMAGUCHI, Osaka-shi (JP)

Correspondence Address: SIDLEY AUSTIN LLP, 717 NORTH HARWOOD, SUITE 3400, DALLAS, TX, 75201, US

(73) Assignee: Konica Minolta Holdings, Inc., Tokyo (JP)

(21) Appl. No.: 12/200,029

(22) Filed: Aug. 28, 2008

(30) Foreign Application Priority Data
Sep. 5, 2007 (JP) 2007-229672

(51) Int. Cl. H05K 7/00

(52) U.S. Cl. 361/681

(57) ABSTRACT

An image display apparatus is supported by a supporting member positioned in front of the viewer's face. The supporting member is formed into a shape that allows it to fit into a face piece. Thus, the viewer is allowed to view an image displayed by the image display apparatus while wearing the face piece. Moreover, when the supporting member fits into the face piece, a face contact portion of the supporting member is held in contact with the viewer's face. At this point, since the face contact portion is formed so as to be symmetric with respect to a plane perpendicular to a line connecting the viewer's eyes, it is possible to easily prevent the supporting member from becoming askew on the face when the supporting member fits into the face piece. This helps prevent the image display apparatus supported by the supporting member from becoming askew while operations are carried out with the face piece placed on the face.

This application is based on Japanese Patent Application No. 2007-229672 filed on Sep. 5, 2007, the contents of which are hereby incorporated by reference.

### BACKGROUND OF THE INVENTION

1. Field of the Invention

The present invention relates to an image display unit having an image display apparatus supported in front of the viewer's eye by a supporting member, and a face piece unit composed of the image display unit and a face piece placed on the viewer's face.

2. Description of Related Art

A head-mounted image display apparatus that is mounted on the viewer's head and that projects a virtual image of the image generated by the display device onto the viewer's pupil is generally known as a so-called HMD (head-mounted display). Among these devices, an HMD disclosed in JP-A-H11-296095 has a dustproof member arranged between a holder that holds an LCD serving as a display device and an entrance surface of a prism used in an eyepiece optical system, that is, the surface where image light from the LCD enters, so as to prevent dirt such as dust from adhering to the light exit surface of the LCD and the entrance surface of the prism.

Incidentally, HMDs are considered to be applicable not just to general consumer goods, but for the purpose of assisting the user in carrying out operations smoothly by providing various information for the user. To use the HMDs for such a purpose, the HMDs are required to have a construction that allows them to be used in combination with other structural members used for that purpose. An example of such structural members used for, for example, supporting rescue operations in disaster situations is a dustproof/waterproof mask that is a type of face piece placed on the face.

However, conventional HMDs including the HMD disclosed in JP-A-H11-296095 do not have a construction intended to be used in combination with a face piece. As a result, the following problem may arise. When the HMD is used in combination with the face piece (that is, the face piece is mounted on the image display apparatus with the image display apparatus positioned in front of the viewer's eye), the image display apparatus, along with the supporting member, becomes askew with one side higher/lower than the other in the middle of various operations. This interferes with the use of the image display apparatus.

### SUMMARY OF THE INVENTION

In view of the conventionally experienced problems discussed above, it is an object of the present invention to provide an image display unit that can prevent an image display apparatus from becoming askew while operations are carried out with a face piece placed on the face by ingeniously designing the shape or construction of a supporting member that supports the image display apparatus inside the face piece, and to provide a face piece unit having a face piece that houses the image display apparatus and the supporting member of the image display unit.

According to one aspect of the present invention, an image display unit is provided with: an image display apparatus displaying an image; and a supporting member positioned in front of a viewer's face for supporting the image display apparatus. Here, the supporting member is formed into a shape that allows the supporting member to fit into a face piece that is placed on the viewer's face, and includes a face contact portion that is held in contact with the viewer's face when the supporting member fits into the face piece, the face contact portion being formed so as to be symmetric with respect to a plane perpendicular to a line connecting the viewer's eyes.

According to another aspect of the present invention, a face piece unit is provided with an image display unit and a face piece. Here, the image display unit is the above-described image display unit according to the invention, and the face piece is placed on the viewer's face with the image display apparatus and the supporting member of the image display unit housed inside the face piece.

According to the present invention, since the face contact portion of the supporting member is formed so as to be symmetric with respect to a plane perpendicular to a line connecting the viewer's eyes when the supporting member fits into the face piece, it is possible to prevent the image display apparatus, along with the supporting member, from becoming askew on the face while operations are carried out with the face piece placed on the face, and thus makes it possible to use the image display unit or carry out support operations with the face piece placed on the face without any problem.

### BRIEF DESCRIPTION OF THE DRAWINGS

This and other objects and features of the present invention will become clear from the following description, taken in conjunction with the preferred embodiments with reference to the accompanying drawings in which:

FIG. 1 is a perspective view of an image display unit, as seen from the inside thereof, constituting a face piece unit embodying the present invention;

FIG. 2 is a perspective view showing an outline of the construction of the face piece unit provided with the image display unit and a face piece;

FIG. 3 is a perspective view schematically showing another construction of the face piece;

FIG. 4A is a front view of a face piece unit using the face piece shown in FIG. 3;

FIG. 4B is a back view of the face piece unit shown in FIG. 4A;

FIG. 5 is a perspective view showing an outline of the construction of the image display unit;

FIG. 6 is a sectional view showing an outline of the construction of the image display apparatus provided in the image display unit;

FIG. 7 is a perspective view showing another example of the construction of the supporting member provided in the image display unit;

FIG. 8 is a sectional view of the belt provided in the image display unit;

FIG. 9 is a perspective view schematically showing another construction of the image display unit; and

FIG. 10 is an exploded perspective view of a face piece unit to which the image display unit shown in FIG. 9 is applied.

### DETAILED DESCRIPTION OF PREFERRED EMBODIMENTS

Hereinafter, an embodiment of the present invention will be described with reference to the drawings.

### 1. A Face Piece Unit

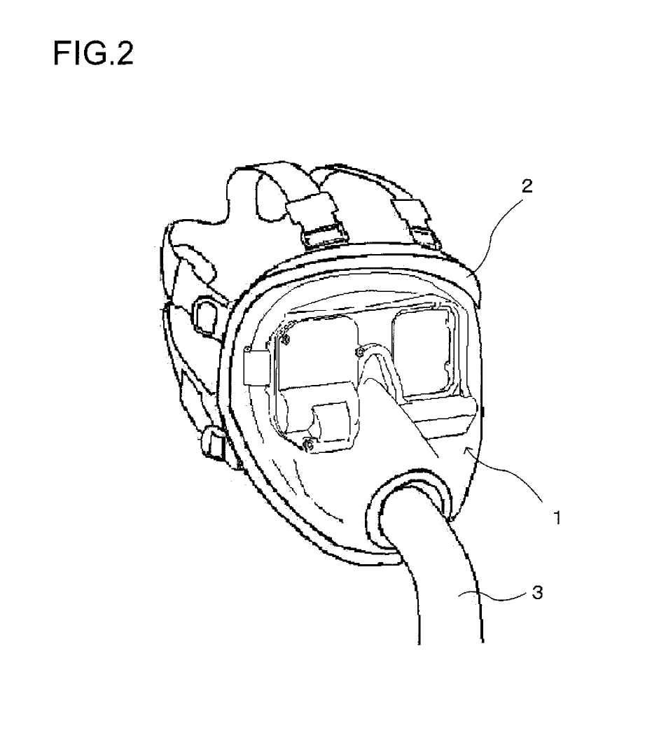

FIG. 2 is a perspective view showing an outline of the construction of a face piece unit according to the embodiment. This face piece unit is composed of an image display unit 1 and a face piece 2.

The image display unit 1 displays an image and presents the viewer with the image as a virtual image, while allowing the viewer to view an outside world image on a see-through basis. The image display unit 1 will be described in detail later.

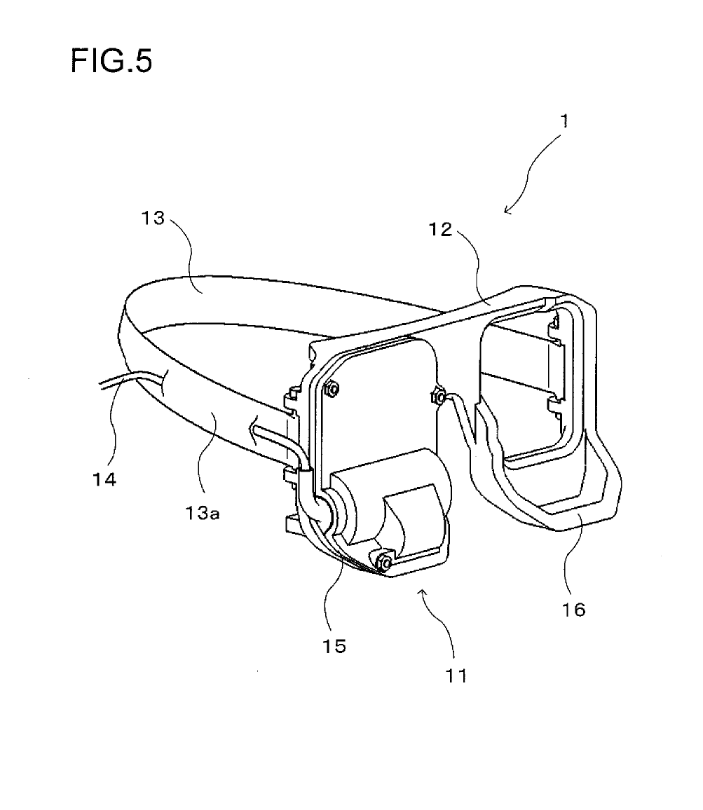

The face piece 2 is placed on the viewer's face. In this embodiment, after the image display unit 1 is mounted on the viewer's head, the face piece 2 is placed thereon so as to cover the image display unit 1. In other words, the face piece 2 is placed on the viewer's face with an image display apparatus 11 and a supporting member 12 (of which both will be described later and are shown in FIG. 5) of the image display unit 1 housed inside the face piece 2. The face piece 2 is built, for example, as a dustproof/waterproof mask having resistance to dust and water. Air is supplied to the inside of the face piece 2 from an unillustrated air cylinder through a hose 3.

As described above, the face piece unit is composed of the image display unit 1 and the face piece 2. Thus, using the image display unit 1 and the face piece 2 in combination such that the image display unit 1 is made to display information on an instruction from the leader or an outside image taken with an infrared camera allows the viewer to carry out rescue operations while viewing it in a time of disaster. This makes it possible to smoothly carry out the operations in disaster situations. Incidentally, the dustproof/waterproof mask is also called an air breathing apparatus or an air-supplied respirator.

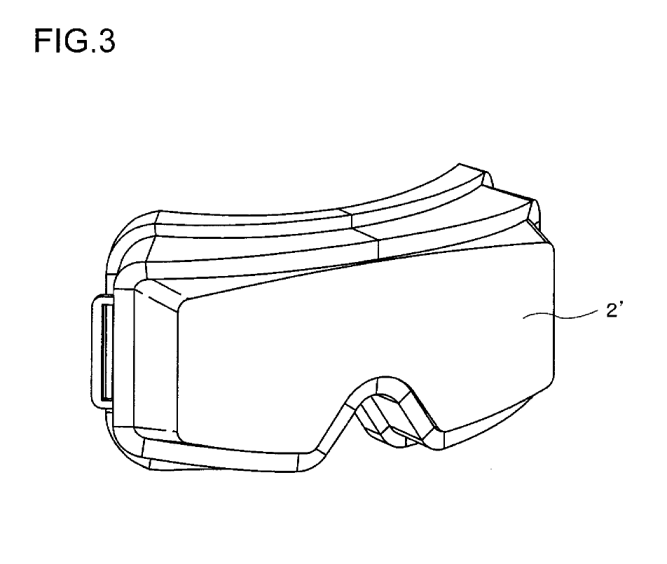

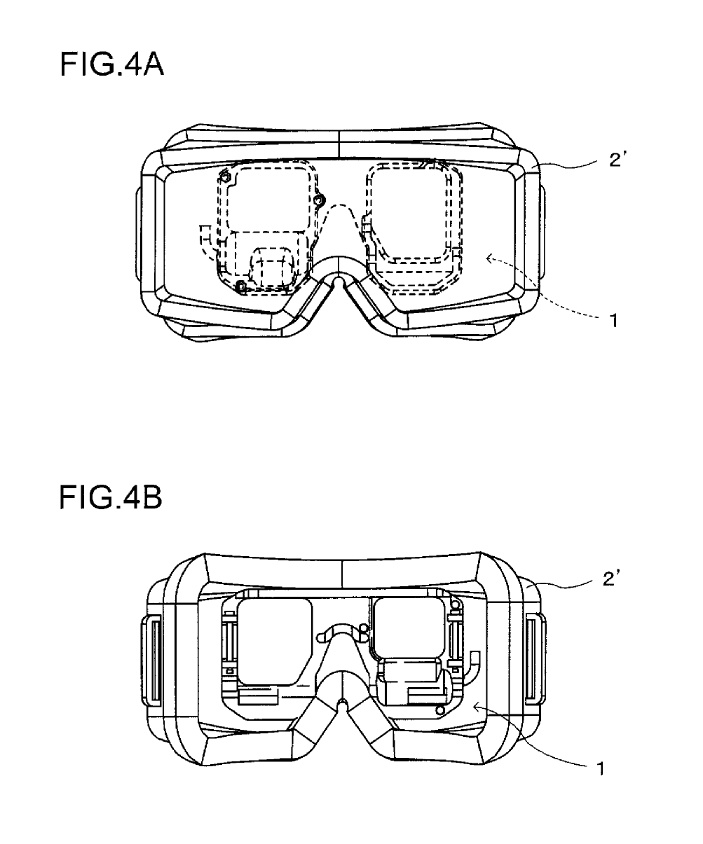

It is also possible to use the above-described image display unit 1 in combination with a face piece 2′ shown in FIG. 3. FIG. 3 is a perspective view schematically showing the construction of the face piece 2′. The face piece 2′ is built as a goggle. Here, FIG. 4A is a front view of a face piece unit using the face piece 2′, and FIG. 4B is a back view of this face piece unit. In these figures, a belt used for attaching the face piece 2′ to the head is not shown. By using such a face piece unit, in a ski resort, for example, it is possible to inform a skier, that is, a viewer, of a current position, a route, weather information and the like by displaying them on the image display unit 1.

### 2. The Image Display Unit

Next, the image display unit 1 will be described in detail. FIG. 5 is a perspective view showing an outline of the construction of the image display unit 1. The image display unit 1 is provided with an image display apparatus 11, a supporting member 12, a belt 13, and a cable 14. The following is a step-by-step description of the image display unit 1.

### 2-1. The Image Display Apparatus

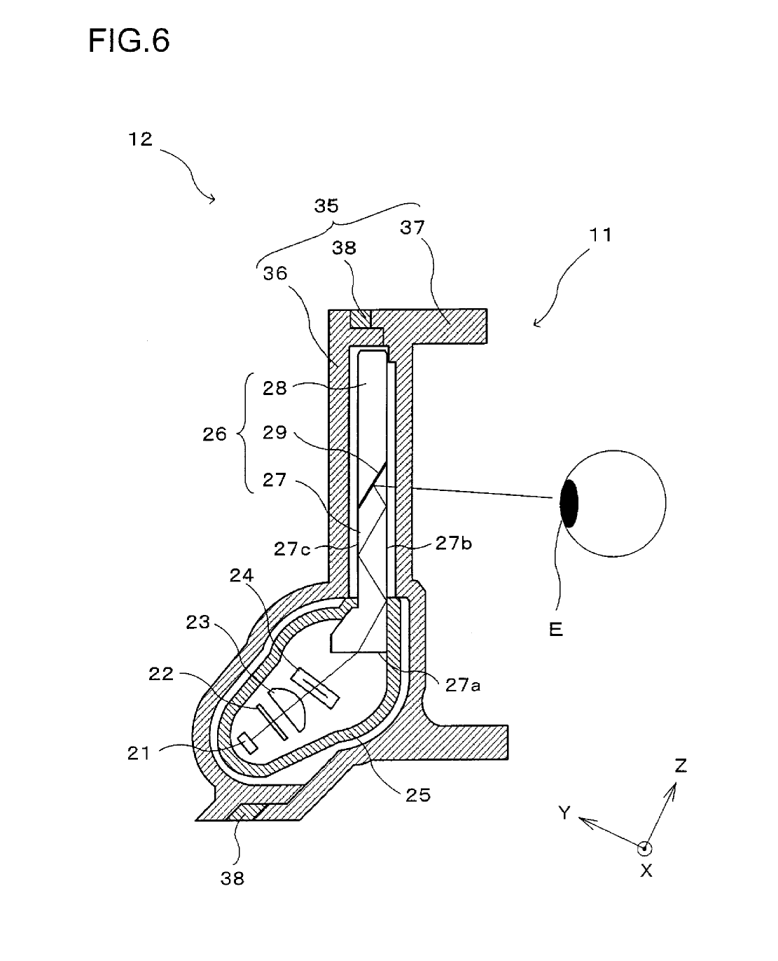

FIG. 6 is a sectional view showing an outline of the construction of the image display apparatus 11. The image display apparatus 11 displays an image, and has a light source 21, a unidirectional diffuser plate 22, a focusing lens 23, a display device 24, and an eyepiece optical system 26. The light source 21, the unidirectional diffuser plate 22, the focusing lens 23, and the display device 24 are placed inside an enclosure 25, and part of the eyepiece optical system 26 (part of an eyepiece prism 27, which will be described later) is also placed inside the enclosure 25. The cable 14 is placed through the enclosure 25 and an enclosure 35, which will be described later, of the supporting member 12, such that the light source 21 and the display device 24 are supplied with drive power or an image signal.

In this embodiment, the image display apparatus 11 has a shape that substantially fits the shape of the above-described face piece 2 (see FIG. 2) so that the image display apparatus 11 can be placed inside the face piece 2, and different optical elements are arranged in accordance with the shape of the image display apparatus 11. For example, the light source 21 is arranged in a position lower than the position of the viewer's pupil, and different optical elements are arranged such that light from the light source 21 is made to travel upward and eventually directed to the viewer's pupil.

For the sake of convenience, the different directions mentioned in the following description are defined as follows. The axis optically connecting between the center of the display area of the display device 24 and the center of the optical pupil E formed by the eyepiece optical system 26 is called the optical axis. Assuming that the optical path from the light source 21 to the optical pupil E is straightened, the direction of the optical axis is called the Z-direction. The direction perpendicular to the optical-axis-incidence plane of a hologram optical element 29, which will be described later, provided in the eyepiece optical system 26 is called the X-direction, and the direction perpendicular to the ZX-plane is called the Y-direction. Here, the “optical-axis-incidence plane” of the hologram optical element 29 denotes the plane that includes both the optical axis of the light incident on the hologram optical element 29 and the optical axis of the light reflected therefrom, which is to say the YZ-plane. In the following description, the optical-axis-incidence plane is also referred to simply as the “incidence plane”. In this embodiment, whether a value is positive or negative is of no significance in any of the X-, Y-, and Z-directions.

The light source 21 illuminates the display device 24, and is built with, for example, an RGB composite LED that emits light in three wavelength bands of 462±12 nm (B (blue) light), 525±17 nm (G (green) light), and 635±11 nm (R (red) light), as given in terms of the light intensity peak wavelength combined with the half peak light intensity wavelength width. As a result of the light source 21 emitting light in predetermined wavelength widths in this way, the image light obtained by illuminating the display device 24 has predetermined wavelength widths. Thus, when the image light is diffracted by the hologram optical element 29, which will be described later, at the position of the optical pupil E, the viewer can view the image over the entire viewing angle. The peak wavelengths of the light source 21 for the different colors are set near the peak wavelengths of the diffraction efficiency, which will be described later, of the hologram optical element 29, and this leads to enhanced light use efficiency.

Built with an LED that emits RGB light, the light source 21 can be realized inexpensively, and, as it illuminates the display device 24, allows it to display a color image, making it possible to present the viewer with the color image. Moreover, since individual LEDs have narrow light emission wavelengths, using a plurality of them makes it possible to display a bright image with accurate color reproduction.

The unidirectional diffuser plate 22 diffuses the light emitted from the light source 21 at different degrees of diffusion in different directions. More specifically, the unidirectional diffuser plate 22 diffuses the incident light at about 40° in the X-direction and at about 0.5° in the Y-direction. Incidentally, the unidirectional diffuser plate 22 may be omitted.

The focusing lens 23 is built with a cylinder lens that focuses in the Y-direction the light diffused by the unidirectional diffuser plate 22, and is so arranged that the diffused light forms the optical pupil E efficiently.

The display device 24 displays an image by modulating the light emitted from the light source 21 according to image data, and is built with a transmission-type liquid crystal display device that has pixels arrayed in a matrix to form a region that transmits light. The display device 24 is arranged with the longer and shorter sides of its rectangular display area aligned with the X- and Y-directions respectively. The display device 24 may be of a reflection type. Usable as the display device 24 of a reflection type are, for example, a reflection-type liquid crystal display device and a DMD (Digital Micromirror Device, manufactured by Texas Instruments Incorporated).

The eyepiece optical system 26 is an enlargement optical system that presents the viewer with an enlarged virtual image of the image displayed by the display device 24 by guiding the light of the image displayed by the display device 24 to the optical pupil E, and is composed of an eyepiece prism 27 (first transparent substrate), a deflector prism 28 (second transparent substrate), and a hologram optical element 29.

The eyepiece prism 27, on one hand, totally reflects, between two opposite surfaces 27b and 27c, the image light entering through a surface 27a from the display device 24 to eventually direct the image light via the hologram optical element 29 to the viewer's pupil. The eyepiece prism 27, on the other hand, transmits outside light to direct it to the viewer's pupil. The eyepiece prism 27, and also the deflector prism 28, is formed of, for example, acrylic resin. The eyepiece prism 27 has the shape of a plane-parallel plate of which a top-end part is wedge-shaped by being formed increasingly thin toward the top end and of which a bottom-end part is formed increasingly thick toward the bottom end. The eyepiece prism 27 is joined to the deflector prism 28 with adhesive so as to sandwich the hologram optical element 29 arranged at the top end of the former.

The deflector prism 28 is a plane-parallel plate that is substantially inverted U-shaped as seen in a front view; when bonded to the eyepiece prism 27 at the top end and both sides thereof, the deflector prism 28 and the eyepiece prism 27 together form a substantially plane-parallel plate. Joining the deflector prism 28 to the eyepiece prism 27 helps prevent distortion in the outside world image that the viewer views through the eyepiece optical system 26.

Specifically, if the deflector prism 28 is not joined to the eyepiece prism 27, outside light is refracted when it is transmitted through the wedge-shaped top-end part of the eyepiece prism 27, and this produces distortion in the outside world image viewed through the eyepiece prism 27. By contrast, when the deflector prism 28 is joined to the eyepiece prism 27 to form an integral substantially plane-parallel plate, the refraction that outside light suffers when transmitted through the wedge-shaped top-end part of the eyepiece prism 27 is canceled by the deflector prism 28. This helps prevent distortion in the outside world image viewed on a see-through basis.

The opposite surfaces of the eyepiece prism 27 and the deflector prism 28 may be flat or curved. Giving the eyepiece prism 27 and the deflector prism 28 curved surfaces allows the eyepiece optical system 26 to function as an eyesight correcting lens.

The hologram optical element 29 is a volume-phase reflection hologram that diffraction-reflects the image light (light of wavelengths corresponding to three primary colors) emergent from the display device 24 and directs it to the optical pupil E, so that an enlarged image displayed by the display device 24 is, as a virtual image, directed to the viewer's pupil. The hologram optical element 29 is, for example, so fabricated as to diffract (reflect) light in three wavelength bands of 465±5 nm (B (blue) light), 521±5 nm (G (green) light), and 634±5 nm (R (red) light), as given in terms of the diffraction efficiency peak wavelength combined with the half peak diffraction efficiency wavelength width. Here, the diffraction efficiency peak wavelength is the wavelength at which diffraction efficiency is at a peak, and the half peak diffraction efficiency wavelength width is the wavelength width within which diffraction efficiency remains equal to or larger than half the peak of diffraction efficiency.

The reflection hologram optical element 29 exhibits high wavelength selectivity, and thus diffraction-reflects only light in the above wavelength bands (near the exposure wavelengths). Accordingly, the hologram optical element 29 transmits outside light containing wavelengths other than those it diffraction-reflects, and thus exhibits high transmittance to outside light.

Moreover, the hologram optical element 29 has an axis-asymmetric positive optical power; that is, the hologram optical element 29 has a function equivalent to that of an aspherical concave mirror having a positive optical power. This increases the flexibility of the arrangement of the individual optical elements constituting the apparatus, thereby making its miniaturization easier, and makes it possible to present the viewer with an image with satisfactorily corrected aberrations.

Next, the operation of the image display apparatus 11 constructed as described above will be described. The light emitted from the light source 21 is diffused by the unidirectional diffuser plate 22, is then focused by the focusing lens 23, and then enters the display device 24. The light that has entered the display device 24 is modulated pixel by pixel according to image data, and emerges therefrom as image light. Thus, the display device 24 displays a color image.

The image light from the display device 24 then enters, in the eyepiece optical system 26, the eyepiece prism 27 through the bottom-end surface (surface 27a) thereof, is then reflected a plurality of times between the two opposite surfaces 27b and 27c, and then strikes the hologram optical element 29. The light that has struck the hologram optical element 29 is reflected thereon, and is then transmitted through the surface 27b, to eventually reach the optical pupil E. At the position of the optical pupil E, the viewer can view an enlarged virtual image of the image displayed by the display device 24.

On the other hand, the eyepiece prism 27, the deflector prism 28, and the hologram optical element 29 transmit almost all outside light; thus, through these, the viewer can view an outside world image. As a result, the virtual image of the image displayed by the display device 24 is viewed in a form superimposed on part of the outside world image.

As described above, in the image display apparatus 11, the image light emergent from the display device 24 is guided by total reflection inside the eyepiece prism 27 so as to be directed via the hologram optical element 29 to the viewer's pupil. This allows the eyepiece prism 27 and the deflector prism 28 to have a thickness of about 3 mm like a common eyeglasses lens, and thus helps make the image display apparatus 11 compact and lightweight. Moreover, the use of the eyepiece prism 27, inside which the image light from the display device 24 is totally reflected, helps secure high transmittance to outside light, and thus makes it possible to present the viewer with a bright outside world image.

Moreover, since the volume-phase reflection hologram optical element 29 has narrow half peak diffraction efficiency wavelength widths and thus offers high diffraction efficiency, its use makes it possible to present a bright image with high color purity, and also offers high transmittance to outside light, allowing the viewer to view a bright outside world image.

Moreover, as will be understood from the foregoing, the hologram optical element 29 functions as a combiner that directs the image light from the display device 24 and outside light simultaneously to the viewer's pupil. Thus, the viewer can view, via the hologram optical element 29, the image presented by the display device 24 and an outside world image simultaneously.

Moreover, since the eyepiece prism 27 and the deflector prism 28 are joined together with the hologram optical element 29 sandwiched between them, the hologram optical element 29 is not exposed to the outside and thus not exposed to the air. This makes it easier to handle the hologram optical element 29, and makes it possible to keep its optical performance stable.

### 2-2. The Supporting Member

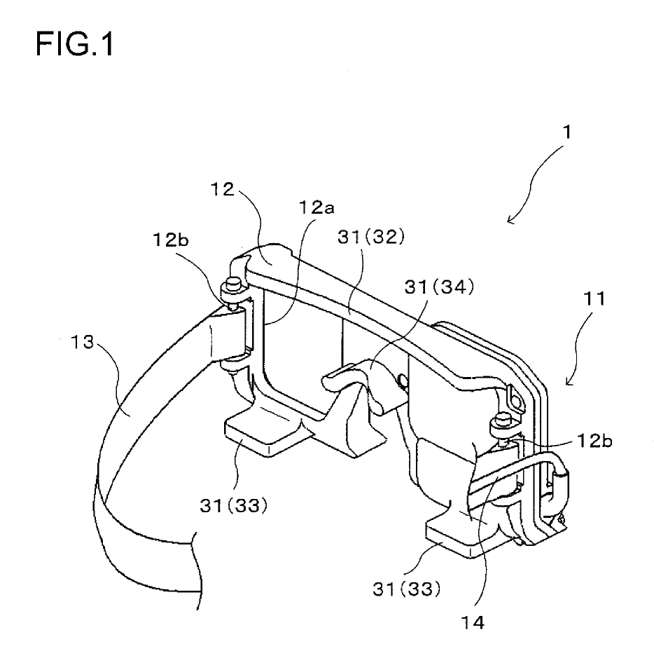

Next, the supporting member 12 will be described. FIG. 1 is a perspective view of the image display unit 1 as seen from the inside thereof. The supporting member 12 serves as a supporting means for supporting the image display apparatus 11 in front of the viewer's face. In this embodiment, the supporting member 12 supports a single image display apparatus 11 so that the image display apparatus 11 is positioned in front of the viewer's right eye. It is needless to say, however, that the supporting member 12 can be so constructed as to support two image display apparatuses 11, with another image display apparatus 11 fitting in an opening 12a in front of the viewer's left eye and fixed to the supporting member 12.

The supporting member 12 is formed into a shape that allows it to fit into the above-described face piece 2 (see FIG. 2) while supporting the image display apparatus 11. Moreover, the supporting member 12 includes a face contact portion 31 that is held in contact with the viewer's face when the supporting member 12 fits into the face piece 2. The face contact portion 31 is composed of a forehead contact portion 32 that makes contact with the viewer's forehead and a cheek contact portion 33 that makes contact with the viewer's cheek. The forehead contact portion 32 is formed as a single component so as to extend from side to side in a position that corresponds to the viewer's forehead. In addition, the cheek contact portion 33 includes two cheek contact portions 33 provided one for each of the viewer's cheeks. As a result, the face contact portion 31 as a whole is symmetric with respect to a plane perpendicular to a line connecting the viewer's eyes.

Moreover, the supporting member 12 includes a nose pad 34. The nose pad 34 is arranged between the forehead contact portion 32 and the cheek contact portions 33. The nose pad 34 is formed into a shape that substantially fits the shape of the viewer's nose, so as to be symmetric with respect to a plane perpendicular to a line connecting the viewer's eyes. It does not matter whether the nose pad 34 comes into contact with the viewer's nose or not when the image display apparatus 11 is supported by the supporting member 12 in front of the viewer's eye. In the former case, the nose pad 34 is also included in the above-described face contact portion 31.

The supporting member 12 is formed into a shape that allows it to fit into the face piece 2, and the image display apparatus 11 is supported by the supporting member 12 so as to be positioned in front of the viewer's eye. This makes it possible for the viewer to view the image displayed by the image display apparatus 11 supported by the supporting member 12 while wearing the face piece 2, allowing him/her to carry out various operations while viewing the image.

Moreover, when the supporting member 12 fits into the face piece 2, the face contact portion 31 of the supporting member 12 is held in contact with the viewer's face. That is, at least, the forehead contact portion 32 makes contact with the viewer's forehead, and the cheek contact portions 33 make contact with the viewer's cheeks. At this point, since the face contact portion 31 is formed so as to be symmetric with respect to a plane perpendicular to a line connecting the viewer's eyes, it is possible to easily prevent the supporting member 12 from becoming askew on the face while the face piece 2 is placed on the face. Specifically, it is possible to easily prevent the supporting member 12 from becoming askew with one side higher/lower than the other while the face piece 2 is placed on the face. This helps prevent the image display apparatus 11 supported by the supporting member 12 from becoming askew while operations are carried out with the face piece 2 placed on the face, and thus makes it possible to use the image display unit 1 or carry out support operations with the face piece 2 placed on the face without any problem.

Moreover, since the forehead contact portion 32 and the cheek contact portions 33 are located on upper and lower parts, respectively, of the viewer's face, it is possible to prevent the image display apparatus 11, along with the supporting member 12, from sliding in the up-and-down direction while operations are carried out with the face piece 2 placed on the face. This also makes the image display apparatus 11 less likely to become askew on the face.

In addition, as shown in FIG. 6, the supporting member 12 is provided with the enclosure 35 that houses the image display apparatus 11 in such a way that the image display apparatus 11 is sealed inside it. The enclosure 35 is composed of a pair of transparent members 36 and 37 and a gasket 38. The transparent members 36 and 37 are formed together into a shape that substantially fits the contour of the image display apparatus 11, and are arranged such that the image display apparatus 11 is sandwiched between them from front and behind, respectively. The gasket 38 is arranged between the transparent members 36 and 37 such that it is brought into close contact with them.

As described above, the image display apparatus 11 is housed and sealed inside the enclosure 35. This secures the dust and water resistance of the image display apparatus 11, and makes it possible to easily remove dirt, if any, from the surface of the enclosure 35 by cleansing or the like. In particular, as a result of the enclosure 35 being composed of the pair of transparent members 36 and 37 and the gasket 38 arranged between them, liquid or dust is surely prevented from penetrating from outside by the presence of the gasket 38. This ensures that the image display apparatus 11 is housed and sealed inside the enclosure 35.

Moreover, as shown in FIG. 5, the supporting member 12 is provided with a supporting portion 15. The supporting portion 15 supports the lower part of the image display apparatus 11 inside the face piece 2 while the face piece 2 is placed on the face with the supporting member 12 fitting into the face piece 2. Due to the presence of the supporting portion 15, it is possible to support the image display apparatus 11 from below with stability while the face piece 2 is placed on the face.

The supporting member 12 is provided also with a dummy portion 16 (first dummy portion). The dummy portion 16 is identical in shape to the supporting portion 15, and is provided in a position such that the dummy portion 16 and the supporting portion 15 are symmetric with each other with respect to a plane perpendicular to a line connecting the viewer's eyes while the face piece 2 is placed on the face. Due to the presence of the dummy portion 16, even when the supporting member 12 receives some force from the face piece 2, for example, in such a case where the image display unit 1 is first mounted on the viewer's head and then the face piece 2 is placed on it, the force thus applied is exerted evenly on the supporting portion 15 and the dummy portion 16 that are symmetric with each other. This helps prevent the image display unit 1 and hence the face piece unit from becoming askew with one side higher/lower than the other.

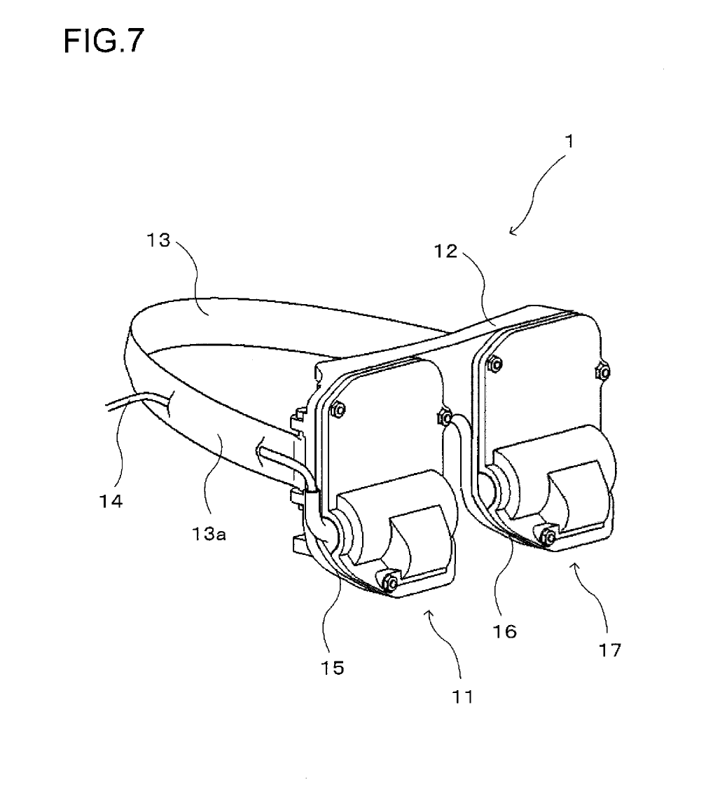

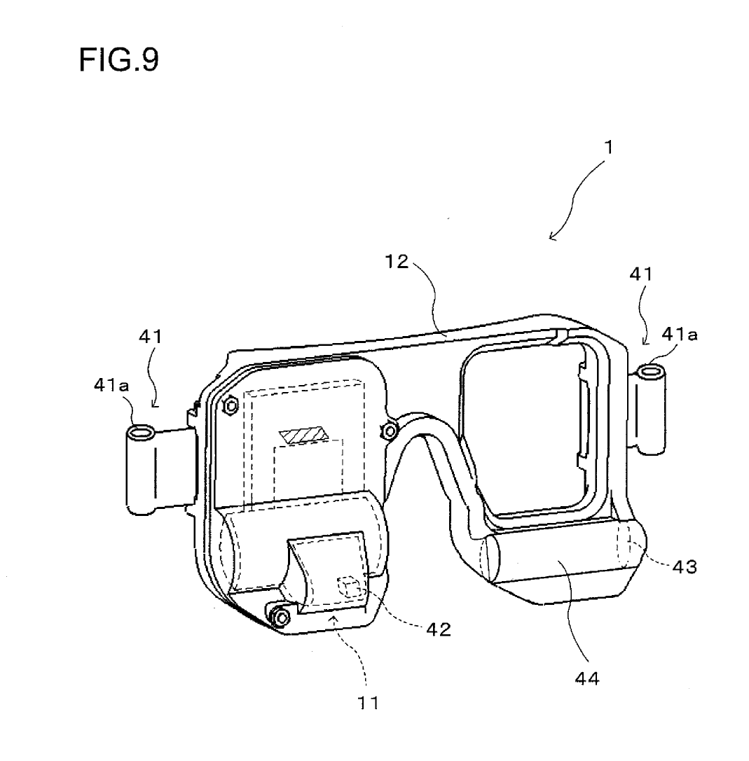

FIG. 7 is a perspective view showing another example of the construction of the supporting member 12. As shown in the figure, the supporting member 12 may be provided with an additional dummy portion 17 (second dummy portion). The dummy portion 17 is substantially identical in shape to the image display apparatus 11. The dummy portion 17 is provided in a position such that, in a case where the supporting member 12 supports the image display apparatus 11 in front of one of the viewer's pupils, the dummy portion 17 is located in front of the other of the viewer's pupils, and the dummy portion 17 and the image display apparatus 11 are symmetric with each other with respect to a plane perpendicular to a line connecting the viewer's eyes. In this case, if the image display apparatus 11 and the dummy portion 17 are of substantially the same weight, it is possible to provide an additional advantage of preventing the image display unit 1 and hence the face piece unit from becoming askew. The dummy portion 17 may be provided with, for example, a receiver portion 42 and a power supply portion 43 (of which both will be described later and are shown in FIG. 9), or a control means for supplying the image display apparatus 11 with an image signal or the like.

### 2-3. The Belt and the Cable

Next, the belt 13 and the cable 14 will be described.

As shown in FIGS. 1 and 5, the belt 13 is a head-mounted member that is mounted on the viewer's head for supporting the supporting member 12, and is formed of, for example, elastic rubber. The belt 13 is connected and secured at both ends thereof to steady pins 12b (see FIG. 1) provided on both ends of the supporting member 12. The belt 13 may be of a length-adjustable type, instead of a stretch type.

As a result of the image display unit 1 being provided with the above-described belt 13, it is possible to secure the supporting member 12 to the viewer's head (or on the viewer's face) with the belt 13 without securing the supporting member 12 to the face piece 2. In addition, by mounting the belt 13 on the viewer's head by connecting it to both ends of the supporting member 12, it is possible to hold the supporting member 12 and the image display apparatus 11 in a proper position regardless of the shape or size of the viewer's head. Furthermore, the elasticity of the belt 13 makes it easy to mount the supporting member 12 on the head, and also makes it possible to secure the supporting member 12 firmly to the head.

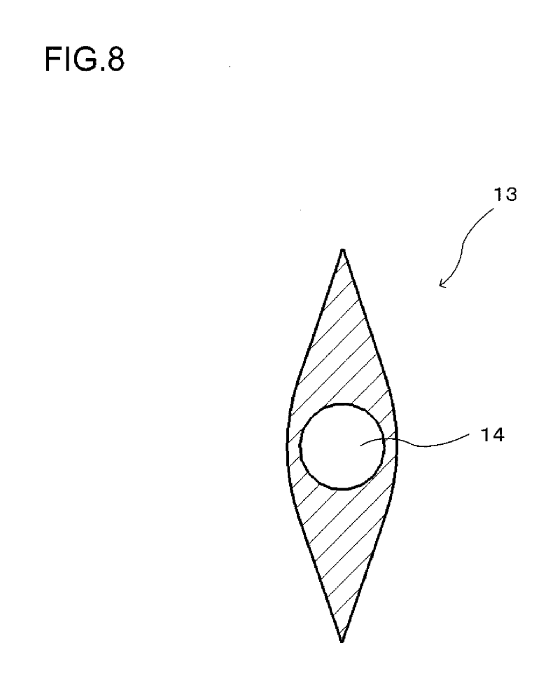

FIG. 8 is a sectional view of the belt 13. As shown in the figure, the belt 13 has in cross-section an outer shape similar to the outline of a human's eye (a thin rhombus-liked shape). That is, the belt 13 is thicker in the middle in cross section than the edge thereof. The use of such a belt 13 makes the middle part of the belt 13 pressed against the viewer's head positioned on the inward side of the belt 13 (on the side of the viewer) and against the face piece 2 positioned on the outward side of the belt 13 (on the opposite side of the belt 13 from the viewer) when the face piece 2 is placed on the face. This helps remove clearance between the viewer's head and the belt 13 and between the face piece 2 and the belt 13, bringing them into close contact with each other. As a result, it is possible to ensure the airtightness of the face piece 2. Thus, in a case where the face piece 2 is built as a dustproof/waterproof mask, there is no possibility of the air supplied from the air cylinder escaping through the clearance, undesirably shortening the duration of air supply.

The cable 14 feeds at least the drive power and the image signal from an external control means to the image display apparatus 11. As shown in FIGS. 5 and 8, the cable 14 is placed through the belt 13 in at least a part 13a thereof (see FIG. 5) sandwiched between the viewer's head and the face piece 2 when the face piece 2 is placed on the face. The cable 14 can be laid in the manner as described above because the belt 13 has in cross-section an outer shape similar to the outline of a human's eye and is thicker in the middle than the edge thereof.

As a result of the cable 14 being laid in the manner as described above, when the face piece 2 is placed on the face, the cable 14 is placed through the belt 13 in a part thereof where the belt 13 is brought into close contact with the viewer's head and the face piece 2. Thus, the presence of the cable 14 does not create clearance between the viewer's head and the face piece 2. As a result, even when the drive power and the image signal are fed to the image display apparatus 11 by using the cable 14, it is possible to ensure the airtightness of the face piece 2.

### 3. Other Construction of the Image Display Unit

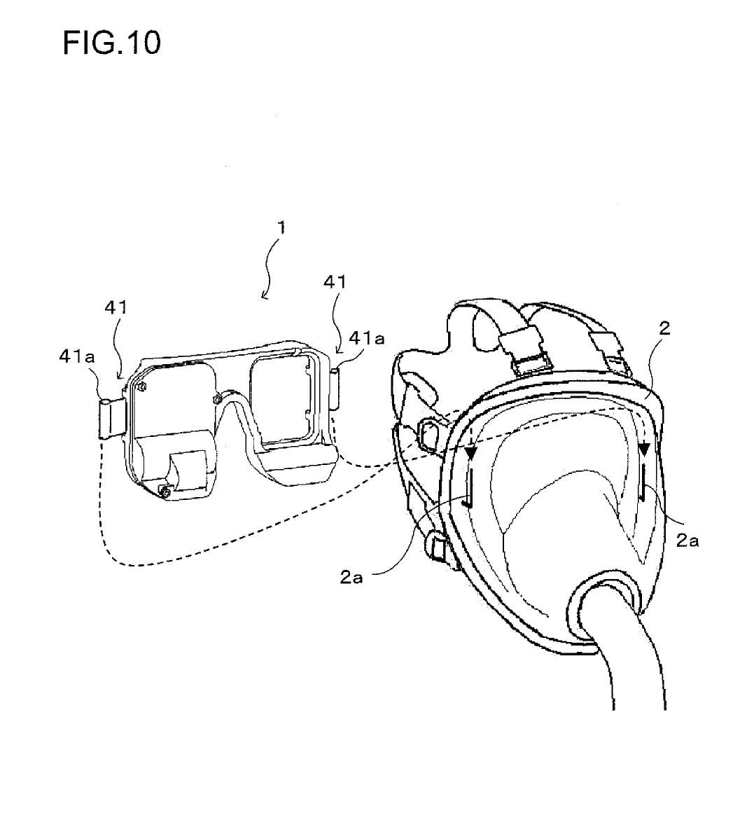

Now, the image display unit 1 may be constructed as follows. FIG. 9 is a perspective view schematically showing another construction of the image display unit 1, and FIG. 10 is an exploded perspective view of a face piece unit to which the image display unit 1 shown in FIG. 9 is applied. This image display unit 1 differs from the image display unit 1 described above only in that, in place of the belt 13, a face piece mounting portion 41 is provided in the supporting member 12, and the receiver portion 42 and the power supply portion 43 are provided in place of the cable 14. Otherwise, this image display unit 1 is the same as the image display unit 1 described above.

The face piece mounting portion 41 can be attached to and detached from the face piece 2, and two face piece mounting portions 41 are provided one for each end of the supporting member 12. The face piece mounting portions 41 each have a cylindrical portion 41a having a hole formed therethrough in an up-and-down direction, the hole allowing a mounting shaft 2a of the face piece 2 to be placed through and removed from the cylindrical portion 41a.

The receiver portion 42 receives an image signal transmitted from the outside (for example, from the control means or image producing portion). The receiver portion 42 here is provided inside the enclosure 25 (see FIG. 6) of the image display apparatus 11; however, it may be provided in any place as long as it is a sealed enclosure. For example, the receiver portion 42 may be provided inside the enclosure 35 of the supporting member 12, or provided inside an enclosure, which will be described later, inside which the power supply portion 43 is provided.

The power supply portion 43 supplies the drive power to drive the image display apparatus 11, and is built, for example, as a battery. The power supply portion 43 is placed inside a lid portion 44 that can be opened and closed. When the lid portion 44 is in a closed state, the lid portion 44 and the supporting member 12 together form a sealed space. Thus, the power supply portion 43 can be considered to be placed inside a sealed enclosure formed with the lid portion 44 and the supporting member 12.

As a result of the image display unit 1 constructed as described above not having the belt 13, when the image display unit 1 is used, the image display unit 1 is attached to the face piece 2 to obtain the face piece unit, and then the face piece unit thus obtained is mounted on the viewer's head (face).

Here, as a result of the supporting member 12 having the face piece mounting portion 41, it is possible to use the image display apparatus 11 by attaching the face piece mounting portion 41 to the face piece 2 only when there is a need to use the image display apparatus 11 in combination with the face piece 2. This helps enhance the convenience. Moreover, making the face piece mounting portion 41 adaptable to a plurality of types of face piece 2 by making the face piece mounting portion 41 slidable side-to-side, for example, allows one supporting member 12 to be used in the plurality of types of face piece 2. This eliminates the need to provide different supporting members 12 one for each of the plurality of types of face piece 2.

In addition, as a result of the image display unit 1 being provided with the receiver portion 42 and the power supply portion 43, it is possible to eliminate the need for the cable 14 for feeding the drive power or the image signal to the image display apparatus 11. This makes it easy for people to operate over a wider area with the face piece 2 placed on their face, and also allows them to operate without delay. Furthermore, the absence of the cable 14 makes the face piece unit easy to wear, and reduces the occurrence of failures. Moreover, as a result of the receiver portion 42 and the power supply portion 43 each being provided inside the sealed enclosure, it is possible to secure the dust and water resistance of the receiver portion 42 and the power supply portion 43.

Needless to say, it is also possible to construct the image display unit 1 or the face piece unit by combining the above-described constructions as appropriate. For example, it is possible to construct the face piece unit by applying the image display unit 1 shown in FIG. 9 to the face piece 2′ shown in FIG. 3. In addition, it is needless to say that the image display unit 1 of this embodiment can be applied to any face piece other than a dustproof/waterproof mask or a goggle.

The present invention can be used for, for example, supporting rescue operations in disaster situations.

The invention can also be expressed as follows and it then offers workings and benefits as described below.

According to one aspect of the invention, an image display unit is provided with: an image display apparatus displaying an image; and a supporting means positioned in front of the viewer's face for supporting the image display apparatus. Here, the supporting means is formed into a shape that allows the supporting means to fit into a face piece that is placed on the viewer's face, and includes a face contact portion that is held in contact with the viewer's face when the supporting means fits into the face piece, the face contact portion being formed so as to be symmetric with respect to a plane perpendicular to a line connecting the viewer's eyes.

With the above construction, the image display apparatus is supported by the supporting means positioned in front of the viewer's face. Since the supporting means is formed into a shape that allows it to fit into the face piece (such as a dustproof/waterproof mask, an air breathing apparatus, an air-supplied respirator, or a goggle), the viewer can view the image for operation-supporting purposes displayed by the image display apparatus with the face piece placed on the face. This allows the viewer to carry out various operations (such as rescue operations in disaster situations) while viewing the image.

Here, when the supporting means fits into the face piece, a face contact portion of the supporting means is held in contact with the viewer's face. At this point, since the face contact portion is formed so as to be symmetric with respect to a plane perpendicular to a line connecting the viewer's eyes, it is possible to easily prevent the supporting means from becoming askew on the face. This helps prevent the image display apparatus supported by the supporting means from becoming askew while operations are carried out with the face piece placed on the face, and thus makes it possible to use the image display unit or carry out support operations with the face piece placed on the face without any problem.

In the image display unit according to the invention, the face contact portion may be provided with: a forehead contact portion making contact with the viewer's forehead; and a cheek contact portion making contact with the viewer's cheek. Since the forehead contact portion and the cheek contact portion are located on upper and lower parts, respectively, of the viewer's face, it is possible to prevent the image display apparatus, along with the supporting means, from sliding in the up-and-down direction and becoming askew on the face while operations are carried out with the face piece placed on the face.

In the image display unit according to the invention, the supporting means may include an enclosure that houses the image display apparatus in such a way that the image display apparatus is sealed inside the enclosure. In this case, since the image display apparatus is housed and sealed inside the enclosure, it is possible to ensure the dust and water resistance of the image display apparatus, and easily remove dirt, if any, from the surface of the enclosure by cleansing.

In the image display unit according to the invention, the enclosure may include: a pair of transparent members that are arranged such that the image display apparatus is sandwiched between the pair of transparent members; and a gasket that is arranged between the pair of transparent members. By arranging the pair of transparent members such that the image display apparatus is sandwiched between them with the gasket interposed therebetween, it is possible to ensure that the image display apparatus is housed and sealed inside the enclosure.

The image display unit according to the invention may further include a head-mounted member mounted on the viewer's head for supporting the supporting means. With this construction, it is possible to secure the supporting means to the viewer's head with the head-mounted member without securing the supporting means to the face piece.

In the image display unit according to the invention, the head-mounted member may be a belt connected to both ends of the supporting means. According to the invention, since the face contact portion of the supporting means is formed so as to be symmetric with respect to a plane perpendicular to a line connecting the viewer's eyes, by mounting the belt on the viewer's head by connecting it to both ends of the supporting means, it is possible to hold the supporting means and the image display apparatus in a proper position regardless of the shape or size of the head. The belt may be of a non-stretch, length-adjustable type, or may be of an elastic type (for example, be made of rubber).

In the image display unit according to the invention, it is preferable that the belt have elasticity. The elasticity of the belt makes it easy to mount the supporting means on the head, and also makes it possible to secure the supporting means firmly to the head.

In the image display unit according to the invention, it is preferable that the belt have in cross-section an outer shape similar to the outline of a human's eye. With this construction, since the belt is thicker in the middle in cross section than the edge thereof, when the face piece is placed on the face, the middle part of the belt is pressed against the viewer's head positioned on the inward side of the belt and against the face piece positioned on the outward side of the belt. This helps remove clearance between the viewer's head and the belt and between the face piece and the belt, bringing them into close contact with each other. As a result, it is possible to ensure the airtightness of the face piece. In addition, as a result of the belt having in cross-section an outer shape similar to the outline of a human's eye, it is possible to, for example, place a cable connected to the image display apparatus so as to pass through the belt.

Preferably, the image display unit according to the invention further includes a cable for feeding at least drive power and an image signal to the image display apparatus, and the cable is placed through the belt in at least a part thereof sandwiched between the viewer's head and the face piece.

As a result of the cable being placed through the belt in a part thereof where the belt is brought into close contact with the viewer's head and the face piece when the face piece is placed on the face, the presence of the cable does not create clearance between the head and the face piece. As a result, even when the cable is connected to the image display apparatus, it is possible to ensure the airtightness of the face piece.

In the image display unit according to the invention, the supporting means may include a face piece mounting portion that can be attached to and detached from the face piece.

With this construction, since the supporting means can be attached to and detached from the face piece, it is possible to use the image display apparatus by attaching the supporting means to the face piece only when there is a need to use the image display apparatus in combination with the face piece. This helps enhance the convenience. Moreover, making the face piece mounting portion adaptable to a plurality of types of face piece, for example, allows one supporting means to be used in the plurality of types of face piece. This eliminates the need to provide different supporting means one for each of the plurality of types of face piece.

The image display unit according to the invention may include a receiver portion receiving an image signal transmitted from the outside; and a power supply portion supplying drive power to drive the image display apparatus. With this construction, it is possible to eliminate the need for the cable for feeding the drive power or the image signal to the image display apparatus. This makes the face piece unit easy to wear, and reduces the occurrence of failures.

In the image display unit according to the invention, it is preferable that the receiver portion and the power supply portion be each placed inside a sealed enclosure. This makes it possible to secure the dust and water resistance of the receiver portion and the power supply portion.

In the image display unit according to the invention, the image display apparatus may include: a light source; a display device displaying an image by modulating light emitted from the light source; and an eyepiece optical system guiding the light of the image displayed by the display device to an optical pupil. Here, the eyepiece optical system may include a volume-phase reflection hologram optical element, and the hologram optical element may diffraction-reflect the image light emergent from the display device and direct the image light to the optical pupil.

With the above construction, the light emitted from the light source is modulated by the display device, and is then eventually directed, as image light, via the eyepiece optical system to the optical pupil. Thus, at the position of the optical pupil, the viewer can view a virtual image of the image displayed by the display device.

Here, the volume-phase reflection hologram optical element used in the eyepiece optical system offers high diffraction efficiency and has narrow half peak diffraction efficiency wavelength widths. Thus, by using such a hologram optical element so as to diffraction-reflect the image light emergent from the display device and direct it to the optical pupil, it is possible to present the viewer with a bright image with high color purity. In addition, by building the eyepiece optical system with the hologram optical element, it is possible to make the eyepiece optical system, and hence the image display apparatus, compact and lightweight.

In the image display unit according to the invention, the hologram optical element may function as a combiner that directs the image light from the display device and outside light simultaneously to a viewer's pupil. In this case, the viewer can view, via the hologram optical element, the image presented by the display device and an outside world image simultaneously.

In the image display unit according to the invention, it is preferable that the hologram optical element have an axis-asymmetric positive optical power. With this construction, it is possible to increase the flexibility of the arrangement of the individual optical elements constituting the image display apparatus, thereby making its miniaturization easier.

In the image display unit according to the invention, the eyepiece optical system may include a first transparent substrate that, on one hand, totally reflects the image light emergent from the display device inside the first transparent substrate so as to eventually direct the image light to the viewer's pupil, and, on the other hand, transmits outside light to direct the outside light to the viewer's pupil. This construction offers high transmittance to outside light, allowing the viewer to view a bright outside world image while viewing the image displayed by the display device.

In the image display unit according to the invention, it is preferable that the eyepiece optical system include a second transparent substrate for cancelling refraction that the outside light suffers when transmitted through the first transparent substrate. With this construction, it is possible to prevent distortion in the outside world image that the viewer views through the eyepiece optical system.

In the image display unit according to the invention, the first transparent substrate and the second transparent substrate may be joined together with the hologram optical element sandwiched between the first transparent substrate and the second transparent substrate. With this construction, the hologram optical element is not exposed to the outside and thus not exposed to the air. This makes it easier to handle the hologram optical element, and makes it possible to keep its optical performance stable.

According to another aspect of the present invention, a face piece unit is provided with an image display unit and a face piece. Here, the image display unit is the above-described image display unit according to the invention, and the face piece is placed on the viewer's face with the image display apparatus and the supporting member of the image display unit housed inside the face piece.

With this construction, in a case where the face piece is, for example, a dustproof/waterproof mask, people can carry out operations in a time of disaster while viewing displayed information from the leader or viewing the image taken with an infrared camera or the like. In a case where the face piece is, for example, a goggle, it is possible to inform a skier who is skiing down the slope of a route while indicating his/her current position, or giving a warning to the skier in real time by displaying weather information.

In the face piece unit according to the invention, the face piece may be a dustproof/waterproof mask. In this case, it is possible to smoothly support rescue operations in disaster situations.

It should be understood that the present invention can be carried out in any manners other than specifically described above, and many modifications and variations are possible within the scope and spirit of the appended claims.

What is claimed is:

1. An image display unit comprising:
an image display apparatus displaying an image; and
a supporting member positioned in front of a viewer's face for supporting the image display apparatus,
wherein the supporting member is formed into a shape that allows the supporting member to fit into a face piece that is placed on the viewer's face, and includes a face contact portion that is held in contact with the viewer's face when the supporting member fits into the face piece, the face contact portion being formed so as to be symmetric with respect to a plane perpendicular to a line connecting viewer's eyes.

2. The image display unit of claim 1,
wherein the face contact portion comprises:
a forehead contact portion making contact with a viewer's forehead; and
a cheek contact portion making contact with a viewer's cheek.

3. The image display unit of claim 2,
wherein the forehead contact portion is formed as a single component so as to extend from side to side in a position that corresponds to the viewer's forehead,
wherein the cheek contact portion comprises two cheek contact portions provided one for each of the viewer's cheeks.

4. The image display unit of claim 1,
wherein the supporting member comprises an enclosure that houses the image display apparatus in such a way that the image display apparatus is sealed inside the enclosure.

5. The image display unit of claim 4,
wherein the enclosure comprises:
a pair of transparent members that are arranged such that the image display apparatus is sandwiched between the pair of transparent members; and
a gasket that is arranged between the pair of transparent members.

6. The image display unit of claim 1, further comprising:
a head-mounted member mounted on a viewer's head for supporting the supporting member.

7. The image display unit of claim 6,
wherein the head-mounted member is a belt connected to both ends of the supporting member.

8. The image display unit of claim 7,
wherein the belt has elasticity.

9. The image display unit of claim 8,
wherein the belt has in cross-section an outer shape similar to an outline of a human's eye.

10. The image display unit of claim 9, further comprising:
a cable for feeding at least drive power and an image signal to the image display apparatus,
wherein the cable is placed through the belt in at least a part thereof sandwiched between the viewer's head and the face piece.

11. The image display unit of claim 1,
wherein the supporting member comprises a face piece mounting portion that can be attached to and detached from the face piece.

12. The image display unit of claim 11,
wherein the face piece mounting portion includes a cylindrical portion having a hole formed therethrough in an up-and-down direction, the hole allowing a mounting shaft of the face piece to be placed through and removed from the cylindrical portion.

13. The image display unit of claim 12 further comprising:
a receiver portion receiving an image signal transmitted from an outside; and
a power supply portion supplying drive power to drive the image display apparatus.

14. The image display unit of claim 13,
wherein the receiver portion and the power supply portion are each placed inside a sealed enclosure.

15. The image display unit of claim 1,
wherein the supporting member comprises a supporting portion supporting a lower part of the image display apparatus inside the face piece while the face piece is placed on the viewer's face with the supporting member fitting into the face piece.

16. The image display unit of claim 15,
wherein the supporting member comprises a first dummy portion that is identical in shape to the supporting portion,
wherein the first dummy portion is provided in a position such that the first dummy portion and the supporting portion are symmetric with each other with respect to the plane perpendicular to the line connecting the viewer's eyes when the face piece is placed on the viewer's face.

17. The image display unit of claim 16,
wherein the supporting member comprises a second dummy portion that is substantially identical in shape to the image display apparatus,
wherein the second dummy portion is provided in a position such that, in a case where the supporting member supports the image display apparatus in front of one of viewer's pupils, the second dummy portion is located in front of another of the viewer's pupils, and the second dummy portion and the image display apparatus are symmetric with each other with respect to the plane perpendicular to the line connecting the viewer's eyes.

18. The image display unit of claim 17,
wherein the second dummy portion and the image display apparatus are of substantially a same weight.

19. The image display unit of claim 1,
wherein the image display apparatus comprises:
a light source;
a display device displaying an image by modulating light emitted from the light source; and
an eyepiece optical system guiding the light of the image displayed by the display device to an optical pupil,
wherein the eyepiece optical system includes a volume-phase reflection hologram optical element,
wherein the hologram optical element diffraction-reflects the image light emergent from the display device and directs the image light to the optical pupil.

20. The image display unit of claim 19,
wherein the hologram optical element functions as a combiner that directs the image light from the display device and outside light simultaneously to a viewer's pupil.

21. The image display unit of claim 19,
wherein the hologram optical element has an axis-asymmetric positive optical power.

22. The image display unit of claim 19,
wherein the eyepiece optical system includes a first transparent substrate that, on one hand, totally reflects the image light emergent from the display device inside the first transparent substrate so as to eventually direct the image light to the viewer's pupil, and, on the other hand, transmits outside light to direct the outside light to the viewer's pupil.

23. The image display unit of claim 22,
wherein the eyepiece optical system includes a second transparent substrate for cancelling refraction that the outside light suffers when transmitted through the first transparent substrate.

24. The image display unit of claim 23,
wherein the first transparent substrate and the second transparent substrate are joined together with the hologram optical element sandwiched between the first transparent substrate and the second transparent substrate.

25. A face piece unit comprising:
an image display unit; and
a face piece,
wherein the image display unit is the image display unit of claim 1,
wherein the face piece is placed on a viewer's face with the image display apparatus and the supporting member of the image display unit housed inside the face piece.

26. The face piece unit of claim 25,
wherein the face piece is a dustproof/waterproof mask.
